(19) United States
(12) Patent Application Publication
(10) Pub. No.: US 2005/0036286 A1
(43) Pub. Date: Feb. 17, 2005

(54) DEVICE FOR COMPUTER FAN AND CASE LIGHT CONTROL

(76) Inventor: Ricky Kuan, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/637,666

(22) Filed: Aug. 11, 2003

(51) Int. Cl. H05K 7/00

(52) U.S. Cl. 361/685

(57) ABSTRACT

A device for a computer fan and case light control has a shell, a microphone, a sound-control adjustment component, a sound detection circuit, a pulse reference circuit, several sets of fan drive circuits, a control circuit, a voltage conversion circuit and a CCFL. The control circuit is respectively connected with the pulse reference circuit, the sound detection circuit, the fan drive circuits and the voltage conversion circuit. The sound detection circuit is respectively connected with the microphone and the sound-control adjustment component. The output terminal of the voltage conversion circuit is connected with the CCFL. A user can control the on/off state or sensitivity of sound through the sound-control adjustment component, and can control the CCFL through sound to provide greater amusement when the device for a computer fan and case light control is assembled on a computer case.

### FIELD OF THE INVENTION

The present invention relates to a device for a computer fan and case light control and, more particularly, to a control panel capable of adjusting a computer fan to the optimum range, controlling the on/off state or the sensitivity of sound, and combining the variation function of a cold cathode fluorescent lamp (CCFL) through sound control.

### BACKGROUND OF THE INVENTION

As shown in FIG. 1, an existent control panel 55 used in a computer case has a switch component 60 for controlling a CCFL and an adjustment component 65 for adjusting the rotation speed of fan. There is no other function. Therefore, its added value is low.

Equipment that uses sound to control the on/off state of a light also exists, e.g., a flashlight whose on/off state is controlled by sound.

If the control panel 55 has the functions of adjusting the rotation speed of fan to the optimum range, controlling the on/off state or the sensitivity of sound, and combining the variation function of a CCFL through sound control, assembly of the control panel 55 on a computer case will be more amusing.

### SUMMARY OF THE INVENTION

One object of the present invention is to provide a control panel, which can adjust the rotation speed of fans to the optimum range, control the on/off state or the sensitivity of sound, and combine the variation function of a CCFL through sound control, hence providing more fun when the control panel is assembled on a computer case.

Another object of the present invention is to provide a control panel, which can enhance the safe use range of a personal computer. Because the control panel can adjust computer fans to the optimum range, noise generated when the fans operate can be effectively reduced.

To achieve the above objects, the present invention proposes a device for a computer fan and case light control, which comprises a shell, a sound detection circuit, a pulse reference circuit, several sets of drive circuits, a voltage conversion circuit and a control circuit. The shell is assembled in a disk drive seat of a transparent computer case. Several fan rotation speed adjustment components, a sound-control adjustment component and a microphone are connected on a front board face of the shell. The sound detection circuit is respectively connected with the microphone and the sound-control adjustment component. The sound detection circuit is used to amplify sound from the microphone and control the on/off state or sensitivity of sound through the sound-control adjustment component. The drive circuits are used to control fans connected therewith. The output terminal of the voltage conversion circuit is connected with a CCFL. The voltage conversion circuit is used to convert an input DC voltage into a high voltage output to drive the CCFF to function. The control circuit is respectively connected with the sound detection circuit, the pulse reference circuit, the fan rotation speed adjustment components, the drive circuits and the voltage conversion circuit. The control circuit is used to receive a potential output by the pulse reference circuit and the fan rotation speed adjustment components, and then send out a pulse signal to the corresponding drive circuit to control the fan connected therewith, or send out a sound-control signal to the voltage conversion circuit to drive the CCFL to turn on, off or flash after comparison.

A light guide component can be connected on each of the fan rotation speed adjustment components and the sound-control adjustment component.

### BRIEF DESCRIPTION OF THE DRAWINGS

The various objects and advantages of the present invention will be more readily understood from the following detailed description when read in conjunction with the appended drawing, in which:

FIG. 1 is a perspective view of a conventional control panel;

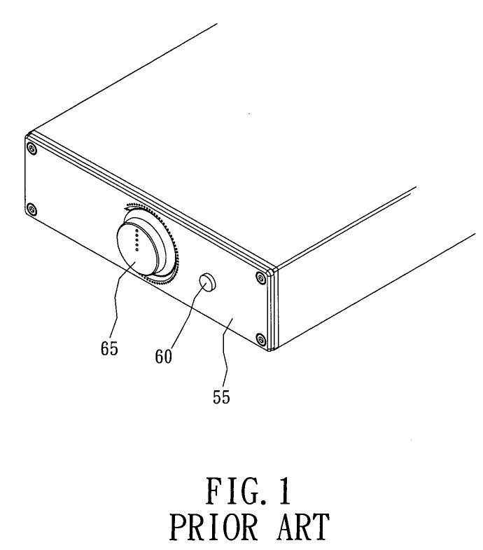

FIG. 2 is an exploded perspective view of the present invention;

FIG. 3 is an assembly view of FIG. 2;

FIG. 4 is a circuit block diagram of the present invention;

FIG. 5 is a circuit diagram of the present invention;

FIG. 6 is a view of the present invention assembled on a computer case; and

FIG. 7 is a perspective view of another embodiment of the present invention.

### DETAILED DESCRIPTION OF THE PREFERRED EMBODIMENTS

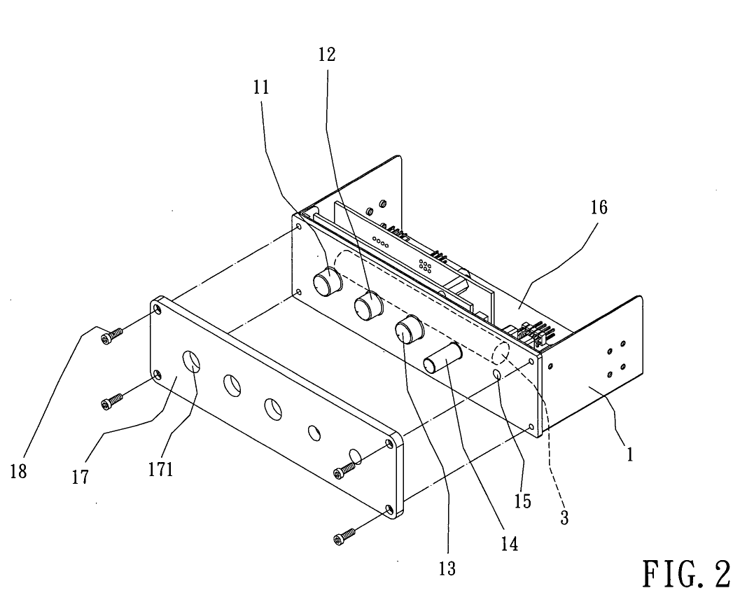

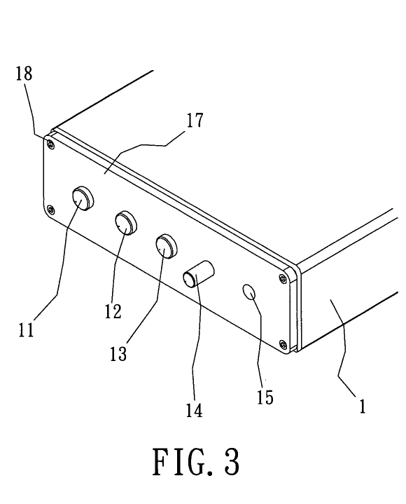

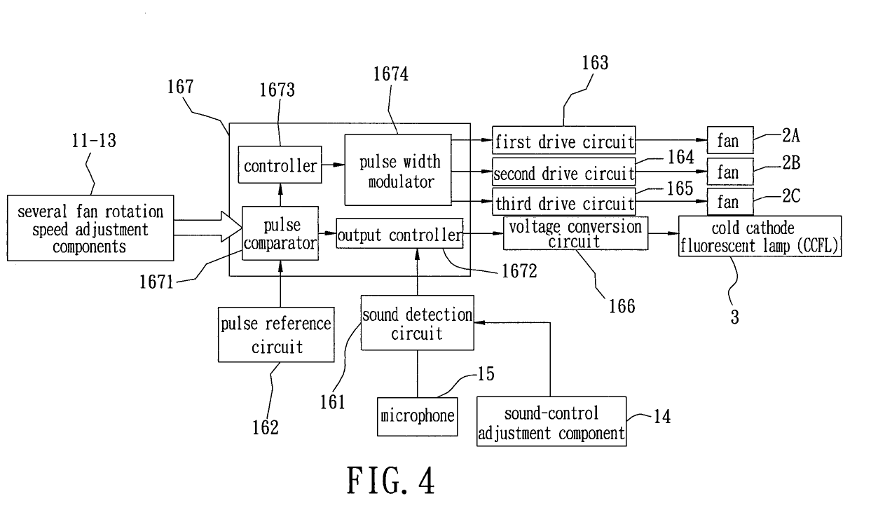

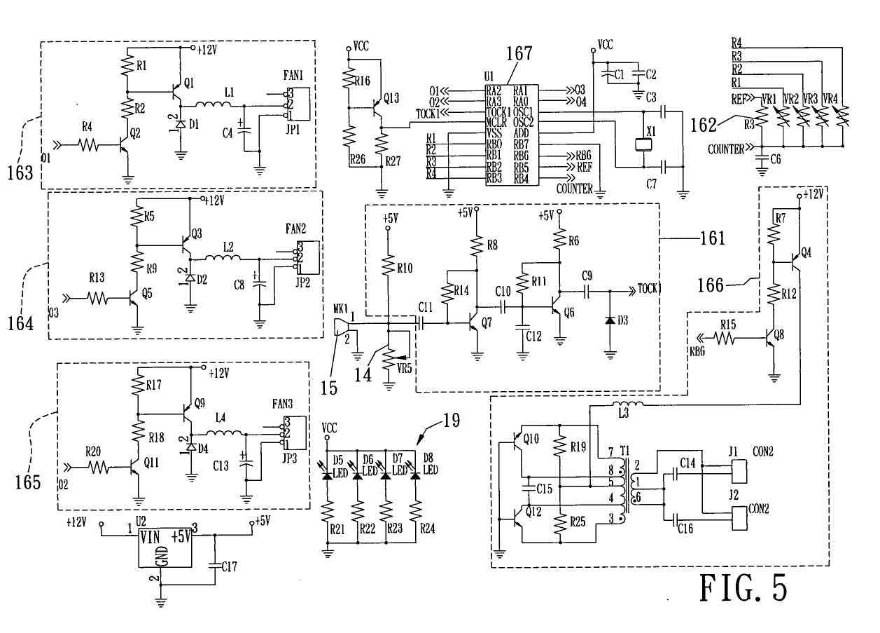

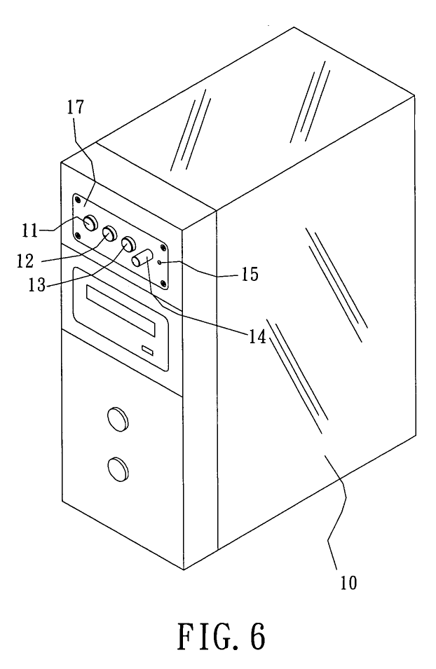

As shown in FIGS. 2 to 6, the present invention provides a device for a computer fan and case light control, which comprises a shell 1, several fan rotation speed adjustment components 11-13, a sound-control adjustment component 14, a sound detection circuit 161, a pulse reference circuit 162, several sets of drive circuits 163-165, a voltage conversion circuit 166, a control circuit 167 and a CCFL 3.

The shell is rectangular, and is assembled in a disk drive seat of a transparent computer case 10. Three fan rotation speed adjustment components 11-13, a sound-control adjustment component (VR5) 14 and a microphone 15 are connected on the front board face of the shell 1, and are also connected with the circuit of a circuit board 16. A panel 17 is connected to the front board face of the shell 1. The panel 17 is locked to the shell 1 through four locking components 18. Several through holes 171 are formed in the panel 17 so that front end portions of the fan rotation speed adjustment components 11-13, the sound-control adjustment component 14 and the microphone 15 can protrude out therethrough.

The circuit of the circuit board 16 includes a sound detection circuit 161, a pulse reference circuit 162, three sets of drive circuits 163-165, a voltage conversion circuit 166 and a control circuit 167.

The sound detection circuit 161 is respectively connected with the microphone 15 and the sound-control adjustment component 14, and is composed of transistors Q6 and Q7, resistors R6, R8, R10, R11 and R14, capacitors C9-C12 and a diode D3.

The sound detection circuit 161 amplifies sound from the microphone 15, and controls the on/off state or sensitivity of sound through the sound-control adjustment component 14.

The pulse reference circuit 162 is a resistor R3.

The first drive circuit 163 is composed of transistors Q1 and Q2, resistors R1, R2 and R4, a diode D1, a capacitor C4, an inductor L1, and an insertion seat JP1, and is used to drive a fan 2A connected therewith.

The second drive circuit 164 is composed of transistors Q3 and Q5, resistors R5, R9 and R13, a diode D2, a capacitor C8, an inductor L2, and an insertion seat JP2, and is used to drive a fan 2B connected therewith.

The third drive circuit 165 is composed of transistors Q9 and Q11, resistors R17, R18 and R20, a diode D4, a capacitor C13, an inductor L4, and an insertion seat JP3, and is used to drive a fan 2C connected therewith.

The voltage conversion circuit 166 is composed of transistors Q4, Q8, Q1O and Q12, a transformer T1, resistors R7, R12, R15, R19 and R25, capacitors C14, C15 and C16, a connection seat CON2 and an inductor L3. The connection seat CON2 is connected with the CCFL 3.

The voltage conversion circuit 166 is driven by the control circuit 17 to convert the input DC voltage into a high voltage output for controlling the function of the CCFL 3.

The control circuit 167 is composed of a microprocessor U1, a quartz crystal X1, capacitors C1-C3 and C7, a transistor Q13, resistors R16, R26 and R27, and is respectively connected with the output terminal of the sound detection circuit 161, the pulse reference circuit 162, the fan rotation speed adjustment components 11-13, the drive circuits 163-165 and the voltage conversion circuit 166. The control circuit 167 receives a potential outputted by the pulse reference circuit 162 and the fan rotation speed adjustment components 11-13, and then sends out a pulse signal to the corresponding drive circuit 163-165 to control the fans 2A-2C connected therewith, or sends out a sound-control signal to the voltage conversion circuit 166 to drive the CCFL 3 to turn on or off, or flash after comparison.

The internal parts of the control circuit 167 include a pulse comparator 1671, an output controller 1672, a controller 1673 and a pulse width modulator 1674. The pulse comparator 1671 is respectively connected with the pulse reference circuit 162, the fan rotation speed adjustment components 11-13 and the output controller 1672. The output controller 1672 is respectively connected with the sound detection circuit 161 and the voltage conversion circuit 166. The output controller 1672 has a three-stage variation of control light mode. The controller 1673 is respectively connected with the output terminal of the pulse comparator 1671 and the pulse width modulator 1674. The output of the pulse width modulator 1674 is respectively connected with the drive circuits 163-165.

When a user turns the fan rotation speed adjustment component 11 (or 12, 13), the control circuit 167 compares its potential with that of the pulse reference circuit 162 and turn the CCFL 3 on or off or makes it flash through the output controller 1672 therein according to the output signal of the sound detection circuit 161.

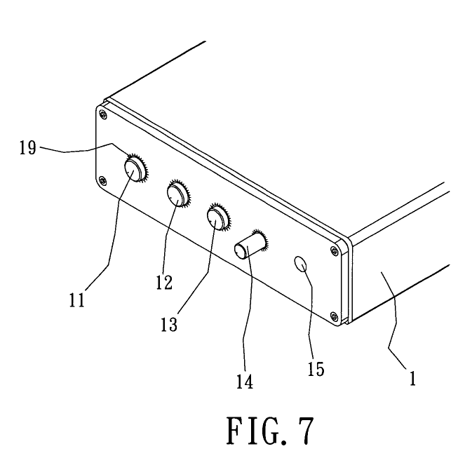

As shown in FIG. 7, a light guide component 19 can be connected to each of the fan rotation speed adjustment components 11-13 and the sound-control adjustment component 14 to accomplish a light-penetration effect when the CCFL 3 flashes.

To sum up, the device for a computer fan and case light control of the present invention can adjust the rotation speed of fan to the optimum range, control the on/off state or the sensitivity of sound, and combine the variation function of a CCFL through sound control, hence providing greater amusement when assembled on a computer case.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A device for a computer fan and case light control, comprising:
a shell assembled in a disk drive seat of a computer case, several fan rotation speed adjustment components, a sound-control adjustment component and a microphone being connected to a front board face of said shell;
a sound detection circuit respectively connected with said microphone and said sound-control adjustment component, said sound detection circuit being used to amplify sound from said microphone and control an on/off state or sensitivity of sound through said sound-control adjustment component;
a pulse reference circuit;
several sets of drive circuits used to control fans connected therewith;
a voltage conversion circuit whose output terminal is connected with a CCFL, said voltage conversion circuit being used to convert an input DC voltage into a high voltage output to drive said CCFF to function; and
a control circuit respectively connected with said sound detection circuit, said pulse reference circuit, said fan rotation speed adjustment component, said drive circuits and said voltage conversion circuit, said control circuit being used to receive a potential output by said pulse reference circuit and said fan rotation speed adjustment component and then send out a pulse signal to the corresponding drive circuit to control the fan connected therewith, or send out a sound-control signal to said voltage conversion circuit to drive said CCFL to turn on or off or flash after comparison.

2. The device for a computer fan and case light control as claimed in claim 1, wherein a panel is connected to the front board face of said shell, said panel is locked with said shell by a plurality of locking components, several through holes are provided in said panel so that front end portions of said fan rotation speed adjustment components, said sound-control adjustment component and said microphone can protrude out of the panel.

3. The device for a computer fan and case light control as claimed in claim 1, wherein a light guide component can be connected on each of said fan rotation speed adjustment components.

4. The device for a computer fan and case light control as claimed in claim 1, wherein a light guide component can be connected on said sound-control adjustment component.

5. A device for a computer fan and case light control, comprising:
a shell assembled on a computer case, a sound-control adjustment component and a microphone being connected on a front board face of said shell;
a sound detection circuit respectively connected with said microphone and said sound-control adjustment component, said sound detection circuit being used to amplify sound from said microphone and control an on/off state or sensitivity of sound through said sound-control adjustment component;
a voltage conversion circuit, wherein an output terminal thereof is connected with a CCFL, said voltage conversion circuit being used to convert an input DC voltage into a high voltage output to drive said CCFF to function; and
a control circuit respectively connected with said sound detection circuit and said voltage conversion circuit, said control circuit being used to receive a signal outputted by said fan rotation speed adjustment component and then send out a pulse signal to said voltage conversion circuit to drive said CCFL to turn on or off or flash after comparison.

6. The device for a computer fan and case light control as claimed in claim 5, further comprising several sets of drive circuits respectively connected with an output terminal of said control circuit, each of said drive circuits being controlled by said control circuit to drive a fan connected therewith.

7. The device for a computer fan and case light control as claimed in claim 5, further comprising a pulse reference circuit and several fan rotation speed adjustment components respectively connected with said control circuit, said fan rotation speed adjustment components being arranged on the front board face of said shell.

8. The device for a computer fan and case light control as claimed in claim 5, wherein a light guide component is connected on each of said fan rotation speed adjustment components.

9. The device for a computer fan and case light control as claimed in claim 5, wherein a light guide component is connected on said sound-control adjustment component.
